(19) United States
(12) Patent Application Publication
(10) Pub. No.: US 2026/0300579 A1
(43) Pub. Date: Oct. 1, 2026

(54) USING A FOUNDATION MODEL THAT HAS BEEN DYNAMICALLY UPDATED BASED ON EXTERNAL MARKERS

(71) Applicant: INTERNATIONAL BUSINESS MACHINES CORPORATION, ARMONK, NY (US)

(72) Inventors: Gregory R. Hintermeister, Rochester, MN (US); Bryan M. Buckland, Austin, TX (US); Chris Moss, Brisbane (AU)

(21) Appl. No.: 19/090,343

(22) Filed: Mar. 25, 2025

(51) Int. Cl. G06F 30/27

(52) U.S. Cl. CPC G06F 30/27

(57) ABSTRACT

Provided are techniques for using a foundation model that has been dynamically updated based on external markers. Data in data sources is monitored for changes to the data, where the data comprises primary data that is used to train a foundation model and secondary data. Artificial Intelligence (AI) governance metrics of the trained foundation model are automatically captured. One or more thresholds for the AI governance metrics are determined, where each of the one or more thresholds is associated with a trigger action to be taken on the foundation model. Based on meeting or exceeding a threshold of the one or more thresholds, the trigger action associated with the threshold is performed to update the foundation model. The updated foundation model is used to generate a prediction in response to receiving an input.

### BACKGROUND

Embodiments of the invention relate to using a foundation model that has been dynamically updated based on external markers.

A foundation model (i.e., a Large X Model (LxM)) may be described as a machine learning model that is trained on very large datasets. The foundation model may then be deployed in different use cases to output predictions.

Training a new foundation model is an effective way to harness Generative Artificial Intelligence (GenAI), especially for use cases with internal business data. However, training a foundation model may be expensive. As a result, a foundation model may become stale over time, depending on how “time-sensitive” the data used for training is. Also, over time, a foundation model may drift due to changes in the data that had been used to train the foundation model, which reduces accuracy of predictions.

### SUMMARY

In accordance with certain embodiments, a computer-implemented method comprising operations is provided for using a foundation model that has been dynamically updated based on external markers. In such embodiments, data in data sources is monitored for changes to the data, where the data comprises primary data stored in one or more primary data sources that is used to train a foundation model and secondary data stored in one or more secondary data sources. Artificial Intelligence (AI) governance metrics of the trained foundation model are automatically captured. One or more thresholds for the AI governance metrics are determined, where each of the one or more thresholds is associated with a trigger action to be taken on the foundation model. Based on meeting or exceeding a threshold of the one or more thresholds, the trigger action associated with the threshold is performed to update the foundation model. The updated foundation model is used to generate a prediction in response to receiving an input.

In accordance with other embodiments, a computer program product comprises one or more computer-readable storage media and program instructions stored on the one or more computer-readable storage media executable by a processor to perform one or more operations for using a foundation model that has been dynamically updated based on external markers. In such embodiments, data in data sources is monitored for changes to the data, where the data comprises primary data stored in one or more primary data sources that is used to train a foundation model and secondary data stored in one or more secondary data sources. Artificial Intelligence (AI) governance metrics of the trained foundation model are automatically captured. One or more thresholds for the AI governance metrics are determined, where each of the one or more thresholds is associated with a trigger action to be taken on the foundation model. Based on meeting or exceeding a threshold of the one or more thresholds, the trigger action associated with the threshold is performed to update the foundation model. The updated foundation model is used to generate a prediction in response to receiving an input.

In accordance with yet other embodiments, a computer system comprises a processor set, one or more computer-readable storage media, and program instructions stored on the one or more computer-readable storage media executable by the processor set to perform one or more operations for using a foundation model that has been dynamically updated based on external markers. In such embodiments, data in data sources is monitored for changes to the data, where the data comprises primary data stored in one or more primary data sources that is used to train a foundation model and secondary data stored in one or more secondary data sources. Artificial Intelligence (AI) governance metrics of the trained foundation model are automatically captured. One or more thresholds for the AI governance metrics are determined, where each of the one or more thresholds is associated with a trigger action to be taken on the foundation model. Based on meeting or exceeding a threshold of the one or more thresholds, the trigger action associated with the threshold is performed to update the foundation model. The updated foundation model is used to generate a prediction in response to receiving an input.

### BRIEF DESCRIPTION OF THE DRAWINGS

Referring now to the drawings in which like reference numbers represent corresponding parts throughout:

FIG. 1 illustrates a computing environment in accordance with certain embodiments.

FIG. 2 illustrates a computing environment of a Data Integrity (DI) sidecar in accordance with certain embodiments.

FIG. 3 illustrates a flow of processing for the DI sidecar in accordance with certain embodiments.

FIG. 4 illustrates, in a flowchart, operations for using a foundation model that has been dynamically updated based on external markers in accordance with certain embodiments.

FIG. 5 illustrates, in a block diagram, details of a machine learning model 500 in accordance with certain embodiments.

### DETAILED DESCRIPTION

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer-readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer-readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

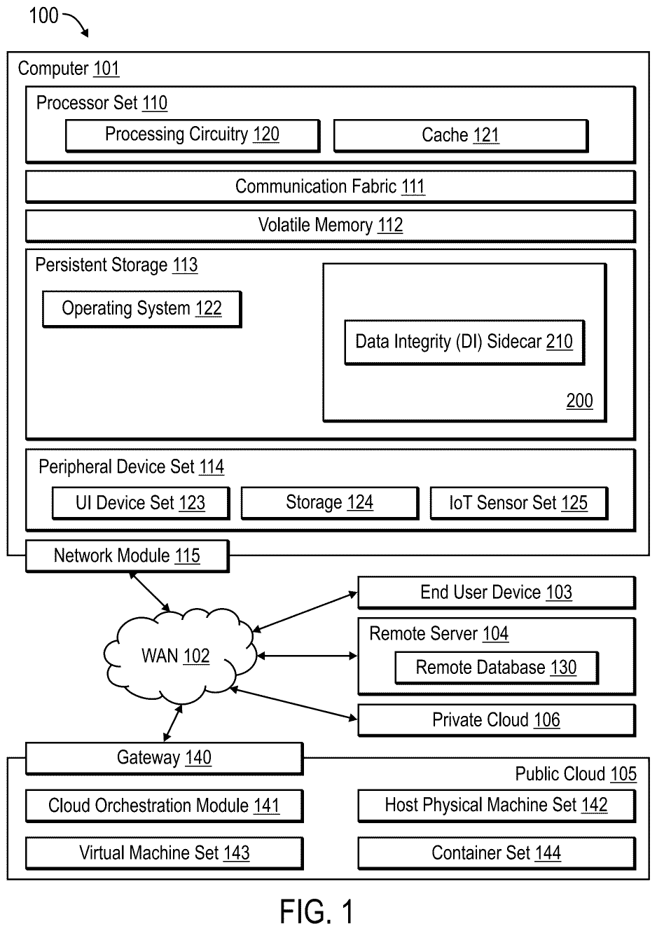

Computing environment 100 of FIG. 1 contains an example of an environment for the execution of at least some of the computer code involved in performing the inventive methods, such as such as a Data Integrity (DI) sidecar 210 of block 200. In addition to block 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set 110 may be located “off chip.” In some computing environments, processor set 110 may be designed for working with qubits and performing quantum computing.

Computer-readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer-readable program instructions are stored in various types of computer-readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 200 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up buses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 200 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer-readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

CLOUD COMPUTING SERVICES AND/OR MICROSERVICES (not separately shown in FIG. 1): private and public clouds 106 are programmed and configured to deliver cloud computing services and/or microservices (unless otherwise indicated, the word “microservices” shall be interpreted as inclusive of larger “services” regardless of size). Cloud services are infrastructure, platforms, or software that are typically hosted by third-party providers and made available to users through the internet. Cloud services facilitate the flow of user data from front-end clients (for example, user-side servers, tablets, desktops, laptops), through the internet, to the provider's systems, and back. In some embodiments, cloud services may be configured and orchestrated according to as “as a service” technology paradigm where something is being presented to an internal or external customer in the form of a cloud computing service. As-a-Service offerings typically provide endpoints with which various customers interface. These endpoints are typically based on a set of APIs. One category of as-a-service offering is Platform as a Service (PaaS), where a service provider provisions, instantiates, runs, and manages a modular bundle of code that customers can use to instantiate a computing platform and one or more applications, without the complexity of building and maintaining the infrastructure typically associated with these things. Another category is Software as a Service (SaaS) where software is centrally hosted and allocated on a subscription basis. SaaS is also known as on-demand software, web-based software, or web-hosted software. Four technological sub-fields involved in cloud services are: deployment, integration, on demand, and virtual private networks.

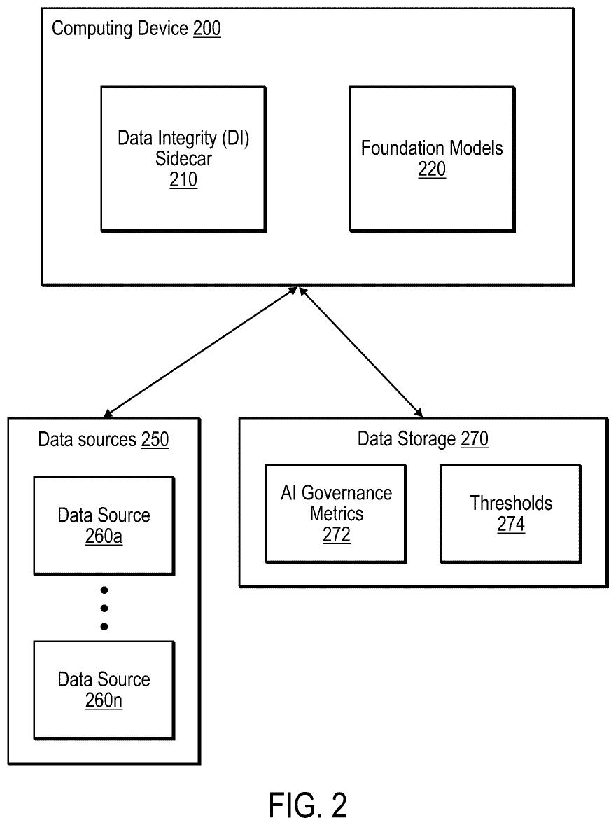

FIG. 2 illustrates a computing environment of a DI sidecar 210 in accordance with certain embodiments. The DI sidecar 210 is connected to foundation models 220. For example, a foundational model 220 may receive requests (e.g., questions) and return predictions (e.g., answers). The DI sidecar 210 is also connected to data sources 260a . . . 260n. In addition, the DI sidecar 210 is connected to data storage 270, which stores AI governance metrics 272 and thresholds 274. A threshold 274 may also be referred to as a threshold limit.

Large Language Models (LLMs) are examples of foundation models 220. LLMs that scrape the Internet for data may have stale data, and so these LLMs may work in some use cases, but not use cases involving current events. Also, domain-specific LLMs in which the data used changes frequently or if the use-case queries are focused on weekly/monthly insights may provide inaccurate predictions at best and harmful predictions at worst. Examples of harmful predictions include: predictions that don't reflect changes in policy or price changes, predictions that reflect unwanted activity, predictions that include inappropriate language from the data that the model was trained, and predictions that don't reflect regulation changes. Either way, the predictions of GenAI are then not trusted, and the investment into using Gen AI may be at risk.

In addition, LLMs may “drift” over time, which leads to inaccuracy of predictions. Even with recent enhancements, data is pulled, put into a specific taxonomy, synthetic data created, and then the LLM model is trained, but the data may still become stale and/or drift.

With a Retrieval Augmented Generation (RAG) architecture, current data is tokenized and stored in a RAG vector database. An AI application interrogates the RAG vector database for content and adds that content into the LLM prompt (as context) so that the LLM responds using that contextual content in the response. However, the data may still become stale. This is further exacerbated by the fact that, typically, data is copied from the source and injected into a specific data store. This is also prone to provide stale and inaccurate data. In addition, it may not be possible to use RAG architecture, so having up-to-date foundation models is useful in use cases involving manufacturing, IoT devices, and some on-device foundation models.

However, the DI sidecar 210 provides a way to measure source data content and automatically update a foundation model once external markers (i.e., thresholds 274) have been surpassed.

The DI sidecar 210 improves foundation model currency by facilitating foundation model re-build based on detecting a predetermined number of changes to the source data. The DI sidecar 210 tracks and stores data state information and triggers foundation model regeneration once certain thresholds 274 have been met. As a result, the DI sidecar 210 enables a foundation model to stay trusted and relevant over long periods of time.

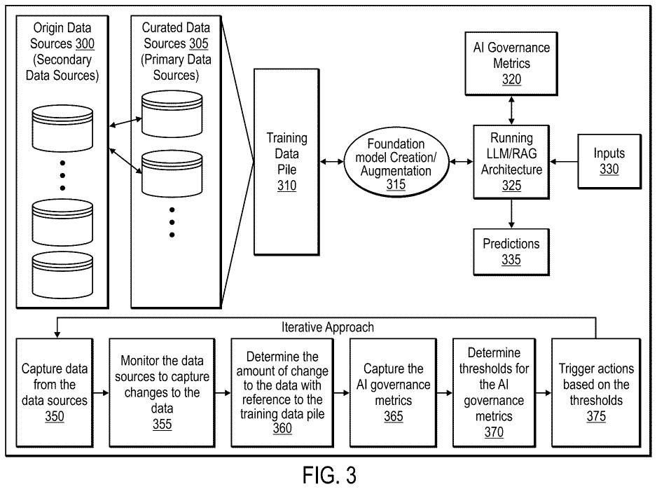

FIG. 3 illustrates a flow of processing for the DI sidecar 210 in accordance with certain embodiments. The DI sidecar 210 orchestrates the foundation model lifecycle. Initially, the DI sidecar 210 monitors the data in the origin data sources 300 (i.e., secondary data sources or secondary data) and the curated data sources 305 (i.e., primary data sources or primary data) being used to create the training data pile 310. That is, the DI sidecar 210 captures not only the primary data sources 305 that are directly used to train the foundation model, but also the secondary data sources 300.

In certain embodiments, there may be many (e.g., hundreds) of origin data sources 300 storing origin data. Some of that origin data may be old, inaccurate, inappropriate, copyrighted, etc. The origin data is curated to become “high quality data sets” (e.g., with the old, inaccurate, inappropriate, copyrighted, etc. removed). The high quality data sets may be merged (i.e., combined) to form the training data pile 310.

In certain embodiments, there may be many curated data sets, and depending on how the foundation model is organized, those many curated data sets may be put into a RAG vector database or may be merged to form the training data pile 310 that is used to train a new foundation model.

The DI sidecar 210 trains the foundation model using the training data pile 310 (block 315), which may run as an LLM/RAG architecture 325. In certain embodiments, the running foundation model receives inputs 330 (e.g., customer tickets) and outputs predictions 335.

Customer tickets are one example of data that changes frequently. In a call center, each customer that calls in with a problem is mapped to a customer ticket. The problem is recorded, the solution is entered, and other details are added (e.g., time to fix, links that helped the engineer solve the problem, etc.). This information, in one example, is added to a RAG architecture to keep the foundation model current. To avoid having the data become stale, the DI sidecar 210 monitors the customer ticket source and, when enough new customer tickets have been resolved, adds those for use in updating the foundation model.

Once the foundation model is trained, the DI sidecar 210 monitors the data sources 300, 305 for changes. At the same time, the DI sidecar 210 tracks the AI governance metrics 320. The DI sidecar 210 determines one or more thresholds for change. Then, if the changes to the data equal (i.e., meet) or exceed the one or more thresholds, the DI sidecar 210 automatically performs a dynamic update of the training data pile 310.

In certain embodiments, the DI sidecar 210 stores default thresholds that are based on rules. For example, one threshold may be based on a rate of change that indicates: If a data source changes a more than Percentage x in Time y, trigger an action. However, if the data source changes less than Percentage x in Time y, do not trigger action yet. That is, this is a time threshold based on sensitivity of data and how temporal the data is (e.g., contains many dates for example). In certain alternative embodiments, an administrator (e.g., an AI engineer) may set thresholds and store the thresholds, and the DI sidecar 210 retrieves the stored thresholds.

In certain embodiments, the trigger may take multiple paths depending on the severity of the threshold being exceeded, and the administrator may monitor those actions and override as needed. Once the training data pile 310 is updated, then the DI sidecar 210 either retrains the foundation model or a RAG vector database is updated. With embodiments, the foundation model may be retrained using various techniques.

In certain embodiments, a system administrator or user may define factors for selecting retraining of the foundation model or update of the RAG vector database. For example, the factors may indicate that for a first set of use cases, the foundation model is to be retrained, and, for a second set of use cases, the RAG vector database is to be updated. As another example, if the foundation model is on the device (i.e., in a manufacturing line with visual recognition), then the foundation model is to be retrained, and, if the foundation model is not on the device, the RAG vector database is to be used.

Once the foundation model is retrained, the DI sidecar 210 resets monitoring to monitor for new changes in data markers. In certain embodiments, the DI sidecar 210 enables the foundation model to be used to perform a task by receiving inputs and outputting predictions.

In particular, the DI sidecar 210 captures data from primary data sources 305 and secondary data sources 300 (block 350) and monitors these data sources 300, 305 to capture changes to the data (block 355). Based on the monitoring, the DI sidecar 210 determines the amount of change with reference to the training data pile 310 (block 360). In certain embodiments, the DI sidecar 210 determines how much of the data in the data sources 300, 305 is different from the data in the training data pile 310.

When data are gathered to train a foundation model, the data may come from many sources (databases, object storage buckets, Internet documentation sites, private enterprise data sources (e.g., internal repositories), product pages, spreadsheets, data stores, etc.). As the training data pile 310 is created a training material, the DI sidecar 210 tracks those data sources 300, 305. For example, when a data integration tool is used to create a “data product” out of many data sources, the DI sidecar 210 captures both the primary data sources 305 and the secondary data sources 300. In another example, when data is stored in buckets, the DI sidecar 210 monitors when images or documents are added to the bucket, as well as, the source of the addition (e.g., a web crawler, etc.).

Moreover, much like a “backup” system, the DI sidecar 210 tracks new and updated data at each data source. As for a time stamp, the DI sidecar 210 tracks the “newness” of the data source. For example, if a document site has very few changes, but the time stamp indicates “Current as of xx/xx/xx”, then the DI sidecar 210 may update the whole content to that timestamp. That is, the DI sidecar 210 may automatically track updates of the data based on timestamps associated with the data.

The DI sidecar 210 captures AI governance metrics (block 365). For each of the foundation models that were trained, the DI sidecar 210 captures the AI governance metrics of those foundation models. For example, CompanyABC-governance generates metadata about a foundation model, including levels of drift, accuracy, etc. The DI sidecar 210 captures this metadata and feeds the metadata into a tracker so that thresholds may be generated by the administrator.

The DI sidecar 210 determines thresholds for the AI governance metrics before triggering action (block 370). Once AI governance metrics are captured, the DI sidecar 210 determines default thresholds for the AI governance metrics that determine whether a trigger action should be taken. The thresholds may be altered or new ones created by the administrator based on the risk tolerance of the applications using the foundation model. For example, a trigger for an AI Governance metric may be that the data is “not accurate”, and thus the trigger may be to train the foundation model on the primary data sources 305 since enough data has changed. In certain embodiments, the DI sidecar 210 determines the default thresholds based on rules.

For example, a threshold (e.g., a rule) may indicate that if a percentage of data sources have changed, then a trigger action is to be initiated. As another example, a threshold may indicate that if a percentage of the data lake house has changed, then initiate a trigger action is to be initiated. As yet another example, AI governance metrics (e.g., drift, harmlessness score, etc.) are used to create thresholds for triggering actions. In certain embodiments, the harmlessness score may represent that the predictions of the foundation model do not contain harmful content. As a further example, a risk level of the changes to the data may exceed thresholds and thus trigger an action to update the foundation model. In certain embodiments, the DI sidecar 210 determines the risk based on the AI governance metrics.

The DI sidecar 210 triggers one or more actions based on the thresholds (block 375). With embodiments, the DI sidecar 210 may perform several trigger actions if thresholds are met. For example, the DI sidecar 210 may retrain the foundation model or may update the RAG architecture with the new data.

In some embodiments, the DI sidecar 210 retrains the full foundation model using a refreshed collection of data (i.e., the training data pile 310).

While retraining models may be expensive (i.e., in terms of time, dedicate computing forcing other workloads to wait, cost of rented cloud infrastructure, etc.), there are many reasons for clients to run with a fully-customized foundation model. In these cases, a threshold may be triggered based on a rule of: “The foundation model can't be used if Accuracy falls to 75%. Accuracy is currently at 80%, and the Accuracy is estimated to fall to 75% in 5 weeks. Trigger retrain now”.

As there are on-going enhancements with how foundation models are updated, new actions may be triggered. For example, in some cases, foundation models may be retrained more cheaply than fully-re-creating a foundation model. Even as this new process is enabled, the new process requires effort and triggers still apply.

If a public model is used (or if immediate changes are desired), the DI sidecar 210 triggers a RAG architecture update. This may update an existing RAG architecture (i.e., updating the RAG vector database) or may fully deploy a new RAG architecture instance to provide a temporary home for the updated data since training a foundation model may take some time (e.g., a couple of weeks), and the users desire access to updated data immediately.

With embodiments, the DI sidecar 210 creates the RAG architecture automatically. For example, the DI sidecar 210 may add the changed data to a RAG architecture for foundation models that are closed, and may trigger a different train and test for foundation models that are open. Open foundation models have their weights and source code available for public access and modification, while closed foundation models have their weights and source code kept secret (i.e., not publicly available).

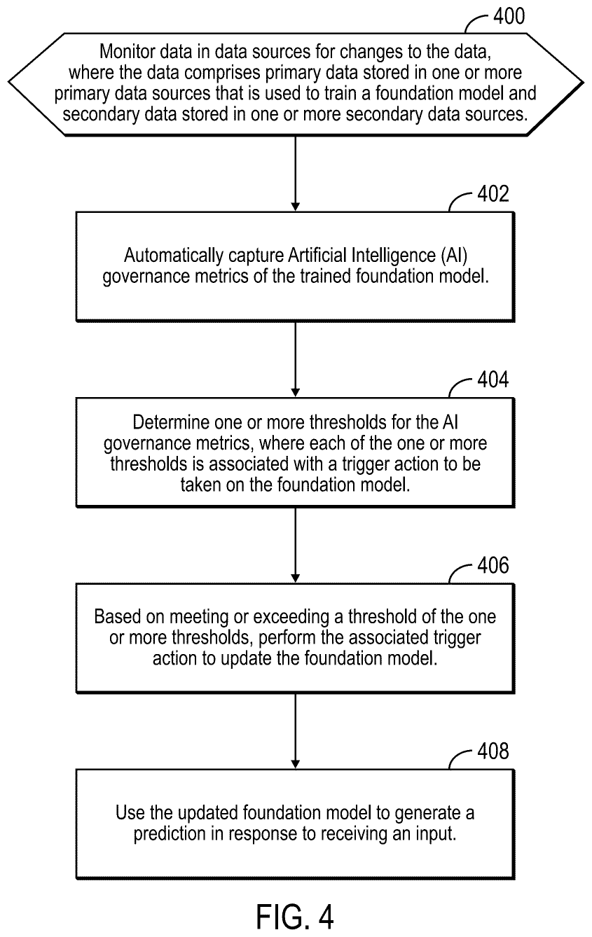

FIG. 4 illustrates, in a flowchart, operations for using a foundation model that has been dynamically updated based on external markers in accordance with certain embodiments. Control begins at block 400 with the DI sidecar 210 monitoring data in data sources for changes to the data, wherein the data comprises primary data stored in one or more primary data sources that is used to train a foundation model and secondary data stored in one or more secondary data sources. The secondary data is curated to form the primary data. In certain embodiments, the primary data is a subset of the secondary data. Since the primary data and the secondary data are stored in different data stores, the DI sidecar 210 monitors both the primary data and the secondary data. In block 402, the DI sidecar 210 automatically captures Artificial Intelligence (AI) governance metrics of the trained foundation model. In block 404, the DI sidecar 210 determines one or more thresholds for the AI governance metrics, where each of the one or more thresholds is associated with a trigger action to be taken on the foundation model. In block 406, the DI sidecar 210, based on meeting or exceeding a threshold of the one or more thresholds, performs the associated trigger action to update the foundation model. In block 408, the DI sidecar 210 uses the updated foundation model to generate a prediction in response to receiving an input.

In certain embodiments, the associated trigger action may be at least one of: retraining the foundation model using an updated training data pile, generating a new RAG vector database with the updated training data pile, and updating an existing RAG vector database with the updated training data pile.

In certain embodiments, determining the one or more thresholds may be at least one of: identifying a first percentage of the one or more primary data sources that have changed, identifying a second percentage of a data lake house that has changed, identifying the AI governance metrics comprising drift and harmlessness score, and identifying a risk level of the changes to the data.

In certain embodiments, the DI sidecar 210 determines the changes based on timestamps associated with the data. For example, if data in the training data pile has an older timestamp than data in the primary data sources, then the DI sidecar 210 determines that the data has changed. The DI sidecar 210 may determine an amount of change to the data with reference to the training data pile.

In addition, the primary data may be a subset of the secondary data. Moreover, the input to the foundation model may be a request (e.g., a question).

Thus, with embodiments, the DI sidecar 210 captures data, captures data changes, captures AI governance metrics, determines and tracks thresholds, and triggers actions based on the amount of data changes compared to the thresholds.

In certain embodiments, the DI sidecar 210 improves a foundation model by facilitating a model re-build in response to detecting a threshold amount of changes to source data associated with the foundation model. Based on data gathered to train the foundation model, the DI sidecar 210 automatically tracks an origin source of the data, where automatically tracking the origin source further includes tracking a primary data source used to directly train the foundation model and one or more secondary data sources including origin databases. for the trained foundation model, the DI sidecar 210 automatically captures artificial intelligence (AI) governance metrics of the foundation model. In response to capturing the AI governance metrics, the DI sidecar 210 determines one or more thresholds to determine whether a trigger action should be taken on the foundation model. Based on meeting (i.e., equal to (“=”)) or exceeding (greater than (“>”)) a threshold of the one or more of the thresholds, the DI sidecar 210 performs the trigger action associated with that threshold. On the other hand, based on not meeting or exceeding (i.e., less than (“<”)) a particular threshold, the associated trigger action is not performed.

In certain embodiments, the trigger action further includes at least one of: retraining the foundation model using refreshed collection of data, and automatically generating and adding a RAG architecture with the refreshed collection of data to the foundation model.

In certain embodiments, automatically tracking the origin source of the data includes automatically tracking a newness of the data based on a timestamp.

In certain embodiments, providing the one or more thresholds further includes at least one of: identifying a first percentage of data sources that have changed and initiating a refresh; identifying a second percentage of the data lake house that has changed; identifying the AI governance metrics comprising drift and harmlessness score; and identifying a risk level of the change.

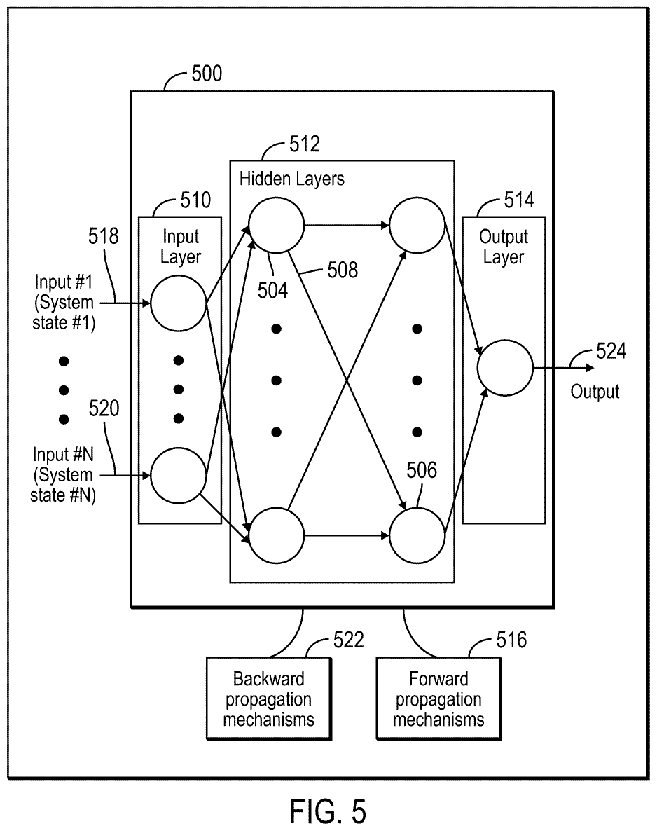

FIG. 5 illustrates, in a block diagram, details of a machine learning model 500 in accordance with certain embodiments. In certain embodiments, the foundations models 220 are implemented using the components of the machine learning model 500.

The machine learning model 500 may comprise a neural network with a collection of nodes with links connecting them, where the links are referred to as connections. For example, FIG. 5 shows a node 504 connected by a connection 508 to the node 506. The collection of nodes may be organized into three main parts: an input layer 510, one or more hidden layers 512, and an output layer 514.

The connection between one node and another is represented by a number called a weight, where the weight may be either positive (if one node excites another) or negative (if one node suppresses or inhibits another). Training the machine learning model 500 entails calibrating the weights in the machine learning model 500 via mechanisms referred to as forward propagation 516 and backward propagation 522. Bias nodes that are not connected to any previous layer may also be maintained in the machine learning model 500. A bias may be described as an extra input of 1 with a weight attached to it for a node.

In forward propagation 516, a set of weights are applied to the input data 518 . . . 520 to calculate the output 524. For the first forward propagation, the set of weights may be selected randomly or set by, for example, a system administrator. That is, in the forward propagation 516, embodiments apply a set of weights to the input data 518 . . . 520 and calculate an output 524.

In backward propagation 522 a measurement is made for a margin of error of the output 524, and the weights are adjusted to decrease the error. Backward propagation 522 compares the output that the machine learning model 500 produces with the output that the machine learning model 500 was meant to produce, and uses the difference between them to modify the weights of the connections between the nodes of the machine learning model 500, starting from the output layer 514 through the hidden layers 512 to the input layer 510, i.e., going backward in the machine learning model 500. In time, backward propagation 522 causes the machine learning model 500 to learn, reducing the difference between actual and intended output to the point where the two come very close or coincide.

The machine learning model 500 may be trained using backward propagation to adjust weights at nodes in a hidden layer to produce adjusted output values based on the provided input data 518 . . . 520. A margin of error may be determined with respect to the actual output 524 from the machine learning model 500 and an expected output to train the machine learning model 500 to produce the desired output value based on a calculated expected output. In backward propagation, the margin of error of the output may be measured and the weights at nodes in the hidden layers 512 may be adjusted accordingly to decrease the error.

Backward propagation may comprise a technique for supervised learning of artificial neural networks using gradient descent. Given an artificial neural network and an error function, the technique may calculate the gradient of the error function with respect to the artificial neural network's weights.

Thus, the machine learning model 500 is configured to repeat both forward and backward propagation until the weights of the machine learning model 500 are calibrated to accurately predict an output.

The machine learning model 500 implements a machine learning technique such as decision tree learning, association rule learning, artificial neural network, inductive programming logic, support vector machines, Bayesian models, etc., to determine the output 524.

In certain machine learning model 500 implementations, weights in a hidden layer of nodes may be assigned to these inputs to indicate their predictive quality in relation to other of the inputs based on training to reach the output 524.

With embodiments, the machine learning model 500 is a neural network, which may be described as a collection of “neurons” with “synapses” connecting them.

With embodiments, there may be multiple hidden layers 512, with the term “deep” learning implying multiple hidden layers. Hidden layers 512 may be useful when the neural network has to make sense of something complicated, contextual, or non-obvious, such as image recognition. The term “deep” learning comes from having many hidden layers. These layers are known as “hidden”, since they are not visible as a network output.

In certain embodiments, training a neural network may be described as calibrating all of the “weights” by repeating the forward propagation 516 and the backward propagation 522.

In backward propagation 522, embodiments measure the margin of error of the output and adjust the weights accordingly to decrease the error.

Neural networks repeat both forward and backward propagation until the weights are calibrated to accurately predict the output 524.

In certain embodiments, the machine learning model 500 may be refined based on whether the outputs (e.g., predictions or recommendations), once taken, generate positive outcomes.

The letter designators, such as i, among others, are used to designate an instance of an element, i.e., a given element, or a variable number of instances of that element when used with the same or different elements.

The terms “an embodiment”, “embodiment”, “embodiments”, “the embodiment”, “the embodiments”, “one or more embodiments”, “some embodiments”, and “one embodiment” mean “one or more (but not all) embodiments of the present invention(s)” unless expressly specified otherwise.

The terms “including”, “comprising”, “having” and variations thereof mean “including but not limited to”, unless expressly specified otherwise.

The enumerated listing of items does not imply that any or all of the items are mutually exclusive, unless expressly specified otherwise.

The terms “a”, “an” and “the” mean “one or more”, unless expressly specified otherwise.

Devices that are in communication with each other need not be in continuous communication with each other, unless expressly specified otherwise. In addition, devices that are in communication with each other may communicate directly or indirectly through one or more intermediaries.

A description of an embodiment with several components in communication with each other does not imply that all such components are required. On the contrary a variety of optional components are described to illustrate the wide variety of possible embodiments of the present invention.

When a single device or article is described herein, it will be readily apparent that more than one device/article (whether or not they cooperate) may be used in place of a single device/article. Similarly, where more than one device or article is described herein (whether or not they cooperate), it will be readily apparent that a single device/article may be used in place of the more than one device or article or a different number of devices/articles may be used instead of the shown number of devices or programs. The functionality and/or the features of a device may be alternatively embodied by one or more other devices which are not explicitly described as having such functionality/features. Thus, other embodiments of the present invention need not include the device itself.

The foregoing description of various embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto. The above specification, examples and data provide a complete description of the manufacture and use of the composition of the invention. Since many embodiments of the invention can be made without departing from the spirit and scope of the invention, the invention resides in the claims herein after appended.

What is claimed is:

1. A computer-implemented method, comprising operations for:
monitoring data in data sources for changes to the data, wherein the data comprises primary data stored in one or more primary data sources that is used to train a foundation model and secondary data stored in one or more secondary data sources;
automatically capturing Artificial Intelligence (AI) governance metrics of the trained foundation model;
determining one or more thresholds for the AI governance metrics, wherein each of the one or more thresholds is associated with a trigger action to be taken on the foundation model;
based on meeting or exceeding a threshold of the one or more thresholds, performing the trigger action associated with the threshold to update the foundation model; and
using the updated foundation model to generate a prediction in response to receiving an input.

2. The computer-implemented method of claim 1, wherein the associated trigger action further comprises operations for at least one of:
retraining the foundation model using an updated training data pile;
generating a new Retrieval-Augmented Generation (RAG) vector database with the updated training data pile; and
updating an existing RAG vector database with the updated training data pile.

3. The computer-implemented method of claim 1, wherein determining the one or more thresholds further comprises at least one of:
identifying a first percentage of the one or more primary data sources that have changed;
identifying a second percentage of a data lake house that has changed;
identifying the AI governance metrics comprising drift and harmlessness score; and
identifying a risk level of the changes to the data.

4. The computer-implemented method of claim 1, wherein the changes are determined based on timestamps associated with the data.

5. The computer-implemented method of claim 1, wherein the primary data comprises a subset of the secondary data.

6. The computer-implemented method of claim 1, wherein the operations further comprise:
determining an amount of change to the data with reference to a training data pile.

7. The computer-implemented method of claim 1, wherein the input to the foundation model comprises a request.

8. A computer program product comprising:
one or more computer-readable storage media; and
program instructions stored on the one or more computer-readable storage media executable by a processor to perform one or more operations, the computer program product comprising:
program instructions to monitor data in data sources for changes to the data, wherein the data comprises primary data stored in one or more primary data sources that is used to train a foundation model and secondary data stored in one or more secondary data sources;
program instructions to automatically capture Artificial Intelligence (AI) governance metrics of the trained foundation model;
program instructions to determine one or more thresholds for the AI governance metrics, wherein each of the one or more thresholds is associated with a trigger action to be taken on the foundation model;
program instructions to, based on meeting or exceeding a threshold of the one or more thresholds, perform the trigger action associated with the threshold to update the foundation model; and
program instructions to use the updated foundation model to generate a prediction in response to receiving an input.

9. The computer program product of claim 8, wherein the associated trigger action further comprises at least one of:
program instructions to retrain the foundation model using an updated training data pile;
program instructions to generate a new Retrieval-Augmented Generation (RAG) vector database with the updated training data pile; and
program instructions to update an existing RAG vector database with the updated training data pile.

10. The computer program product of claim 8, wherein determining the one or more thresholds further comprises at least one of:
program instructions to identify a first percentage of the one or more primary data sources that have changed;
program instructions to identify a second percentage of a data lake house that has changed;
program instructions to identify the AI governance metrics comprising drift and harmlessness score; and
program instructions to identify a risk level of the changes to the data.

11. The computer program product of claim 8, wherein the changes are determined based on timestamps associated with the data.

12. The computer program product of claim 8, wherein the primary data comprises a subset of the secondary data.

13. The computer program product of claim 8, further comprising:
program instructions to determine an amount of change to the data with reference to a training data pile.

14. The computer program product of claim 8, wherein the input to the foundation model comprises a request.

15. A computer system comprising:
a processor set;
one or more computer-readable storage media; and
program instructions stored on the one or more computer-readable storage media to cause the processor set to perform operations comprising:
monitor data in data sources for changes to the data, wherein the data comprises primary data stored in one or more primary data sources that is used to train a foundation model and secondary data stored in one or more secondary data sources;
automatically capture Artificial Intelligence (AI) governance metrics of the trained foundation model;
determine one or more thresholds for the AI governance metrics, wherein each of the one or more thresholds is associated with a trigger action to be taken on the foundation model;
based on meeting or exceeding a threshold of the one or more thresholds, perform the trigger action associated with the threshold to update the foundation model; and
use the updated foundation model to generate a prediction in response to receiving an input.

16. The computer system of claim 15, wherein the associated trigger action further comprising operations to perform at least one of:
retrain the foundation model using an updated training data pile;
generate a new Retrieval-Augmented Generation (RAG) vector database with the updated training data pile; and
update an existing RAG vector database with the updated training data pile.

17. The computer system of claim 15, wherein determining the one or more thresholds further comprising operations to at least one of:
identify a first percentage of the one or more primary data sources that have changed;
identify a second percentage of a data lake house that has changed;
identify the AI governance metrics comprising drift and harmlessness score; and
identify a risk level of the changes to the data.

18. The computer system of claim 15, wherein the changes are determined based on timestamps associated with the data.

19. The computer system of claim 15, wherein the primary data comprises a subset of the secondary data.

20. The computer system of claim 15, further comprising operations to:
determine an amount of change to the data with reference to a training data pile.
